(19) United States
(12) Patent Application Publication
(10) Pub. No.: US 2010/0304027 A1
(43) Pub. Date: Dec. 2, 2010

(54) SUBSTRATE PROCESSING SYSTEM AND METHODS THEREOF

(75) Inventors: Wei Ti Lee, San Jose, CA (US); Lai Ta, Santa Clara, CA (US); Srinivas Guggilla, San Jose, CA (US); Kevin Moraes, Fremont, CA (US); Olkan Cuvalci, Sunnyvale, CA (US); Regan Young, Newark, CA (US); John Mazzocco, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/789,194

(22) Filed: May 27, 2010

Related U.S. Application Data
(60) Provisional application No. 61/181,438, filed on May 27, 2009.

(51) Int. Cl. C23C 16/44; C23C 16/00

(52) U.S. Cl. 427/255.39; 427/255.7; 427/255.23; 414/805; 427/248.1

(57) ABSTRACT

Embodiments of the invention provide methods for processing substrates within a substrate processing system. In one embodiment, the method provides depositing a material on a substrate within a vapor deposition chamber coupled to a buffer chamber contained within a mainframe while maintaining a pressure of about 1×10⁻⁶ Torr or lower within a transfer chamber contained within the mainframe. The method further includes transferring the substrate from the vapor deposition chamber to the buffer chamber by a substrate handling robot while flowing a gas into the buffer chamber, evacuating the vapor deposition chamber, and maintaining a greater internal pressure within the buffer chamber than in the vapor deposition chamber. In some embodiments, the method includes transferring the substrate from the transfer chamber to a PVD chamber coupled to the transfer chamber by another substrate handling robot and depositing another material on the substrate within the PVD chamber.

### CROSS-REFERENCE TO RELATED APPLICATION

This application claims benefit of U.S. Ser. No. 61/181,438 (APPM/013585L), filed May 27, 2009, which is herein incorporated by reference in its entirety.

### BACKGROUND OF THE INVENTION

1. Field of the Invention

Embodiments of the invention generally relate to processing systems and methods thereof used for processing substrates.

2. Description of the Related Art

Where various deposition processes such as chemical vapor deposition (CVD), atomic layer deposition (ALD), or physical vapor deposition (PVD) are used within a deposition processing system, typically the pressure within the deposition chambers is higher than the pressure within a buffer chamber or a transfer chamber in which the deposition chamber is connected thereto. This differential in pressure helps to limit the flow of contaminants from the buffer or transfer chamber into the deposition chambers when the slit valves are opened to transfer substrates therebetween.

Thus, gases in the higher pressure processing chamber will typically flow into the buffer or transfer chamber when the slit valves are open. While this movement of gas is acceptable or even preferable for many processes, some CVD and ALD processes use or form corrosive gases, such as precursor compounds or by-products which can corrode the interior of the buffer chamber, transfer chambers, robots, or other mainframe parts and cause defects in the coated substrates. If the corrosive gas were to flow into other chambers that are used for PVD processes such as sputtering, the target material for the sputtering process could be contaminated. While one solution used to avoid the damage to the mainframe from the exposure to corrosive gas is to coat the buffer chamber and other chambers with nickel or other substances that resist the corrosive effect of these process gases, such coating can be expensive or even impractical given the increasing size of certain buffer and transfer chambers.

Therefore, there is a need for an improved method and apparatus for processing and handling substrates within a processing system.

### SUMMARY OF THE INVENTION

Embodiments of the invention provide methods for processing substrates within a substrate processing system. In one embodiment, a method provides depositing a first material on a substrate within a vapor deposition chamber coupled to a buffer chamber contained within a mainframe housing of the substrate processing system and transferring the substrate from the vapor deposition chamber to the buffer chamber while maintaining a greater internal pressure within the buffer chamber than in the vapor deposition chamber. The mainframe housing further contains a transfer chamber which may be maintained with an internal pressure of about 1×10⁻⁶ Torr or lower and may have at least one physical vapor deposition (PVD) chamber coupled thereto. Also, the buffer chamber contains a first substrate handling robot and the transfer chamber contains a second substrate handling robot. In other aspects, the method further includes transferring the substrate from the buffer chamber to the transfer chamber, transferring the substrate from the transfer chamber to the PVD chamber by the second substrate handling robot, and depositing a second material over the substrate within the PVD chamber.

The method may further include flowing at least one gas into the buffer chamber and evacuating the vapor deposition chamber while transferring the substrate from the vapor deposition chamber to the buffer chamber. Gases which may be flowed into the buffer chamber include argon, nitrogen, helium, or mixtures thereof. The method may further include maintaining a slit valve in an open position while transferring the substrate from the vapor deposition chamber to the buffer chamber. The slit valve is disposed between the buffer chamber and the vapor deposition chamber.

In some examples, the internal pressure of the buffer chamber may be maintained at about 1 Torr or greater and the internal pressure of the vapor deposition chamber may be maintained at about 100 milliTorr or lower while transferring the substrate from the vapor deposition chamber to the buffer chamber. In other examples, the internal pressure of the buffer chamber may be maintained at about 10 Torr or greater and the internal pressure of the vapor deposition chamber may be maintained at about 10 milliTorr or lower.

In some embodiments, the method further includes transferring the substrate from the buffer chamber to a treatment chamber by the first substrate handling robot and subsequently, transferring the substrate from the treatment chamber to the buffer chamber by the second substrate handling robot. The treatment chamber may be disposed between the transfer chamber and the buffer chamber. A first slit valve may be disposed between the transfer chamber and the treatment chamber and a second slit valve may be disposed between the buffer chamber and the treatment chamber.

The first material may be deposited during a vapor deposition process, such as a chemical vapor deposition (CVD) process or an atomic layer deposition (ALD) process, therefore, the vapor deposition chamber may be a CVD chamber or an ALD chamber. During the vapor deposition process, at least one corrosive compound, such a halogenated compound, may be delivered into the vapor deposition chamber while forming or depositing the first material on the substrate. In some examples, the halogenated compound contains chlorine or fluorine. Exemplary halogenated compounds include titanium tetrachloride, tantalum pentafluoride, tungsten hexafluoride, hafnium tetrachloride, aluminum trichloride, silicon tetrachlorosilane, hexachlorodisilane, derivatives thereof, and combinations thereof.

In another embodiment, the method provides depositing a material on a substrate within a vapor deposition chamber coupled to a buffer chamber contained within a mainframe housing of the substrate processing system, wherein the buffer chamber contains a first substrate handling robot, maintaining an internal pressure of about 1×10⁻⁵ Torr or lower within a transfer chamber contained within the mainframe housing, wherein at least one PVD chamber is coupled to the transfer chamber and the transfer chamber contains a second substrate handling robot, and transferring the substrate from the vapor deposition chamber to the buffer chamber by the first substrate handling robot while maintaining a greater internal pressure within the buffer chamber than in the vapor deposition chamber. In some examples, the internal pressure of the transfer chamber is maintained within a range from about 5×10⁻⁸ Torr to about 1×10⁻⁶ Torr.

In another embodiment, the method provides depositing a material on a substrate within a vapor deposition chamber coupled to a buffer chamber contained within a mainframe housing of the substrate processing system, wherein the material is deposited during a vapor deposition process and at least one halogenated compound is delivered into the vapor deposition chamber during the vapor deposition process. The method further includes transferring the substrate from the vapor deposition chamber to the buffer chamber while maintaining a greater internal pressure within the buffer chamber than in the vapor deposition chamber, flowing at least one gas into the buffer chamber, and evacuating the vapor deposition chamber. The method may further include maintaining a slit valve in an open position while transferring the substrate from the vapor deposition chamber to the buffer chamber. The slit valve is disposed between the buffer chamber and the vapor deposition chamber.

### BRIEF DESCRIPTION OF THE DRAWING

So that the manner in which the above recited features and other features contemplated and claimed herein are attained and can be understood in detail, a more particular description of the invention, briefly summarized below, may be had by reference to one embodiment thereof which is illustrated in the appended drawing. It is to be noted, however, that the appended drawing illustrates only a typical embodiment of this invention and is therefore not to be considered limiting of its scope, for the invention may admit to other equally effective embodiments.

FIG. 1 depicts a processing system which may be used in embodiments described herein.

### DETAILED DESCRIPTION

Embodiments of the invention provide methods for processing substrates within a substrate processing system. In one embodiment, the method provides depositing a material on a substrate within a vapor deposition chamber or other processing chamber coupled to a buffer chamber contained within a mainframe housing, transferring the substrate from the processing or vapor deposition chamber to the buffer chamber by a substrate handling robot while flowing a gas into the buffer chamber, evacuating the vapor deposition chamber, and maintaining a greater internal pressure within the buffer chamber than in the vapor deposition chamber. The vapor deposition chamber may be a chemical vapor deposition (CVD) chamber or an atomic layer deposition (ALD) chamber.

Generally, a transfer chamber also contained within the same mainframe housing may be maintained under a high vacuum (e.g., a pressure of about 1×10⁻⁶ Torr or lower) while the substrate is transferred within the buffer chamber. In some embodiments, the method may include transferring the substrate from the buffer chamber to a treatment chamber disposed between the buffer and transfer chambers, from the treatment chamber to the transfer chamber by another substrate handling robot which may be disposed within the transfer chamber, from the transfer chamber to one of multiple processing chambers (e.g., PVD chamber) coupled to the transfer chamber, and/or between two of the processing chambers. By maintaining a greater internal pressure within the buffer chamber than in the vapor deposition chamber or other processing chambers coupled to the buffer chamber, the transfer chamber may be maintained at high vacuum for transferring substrates between PVD chambers or other chambers coupled to the transfer chamber.

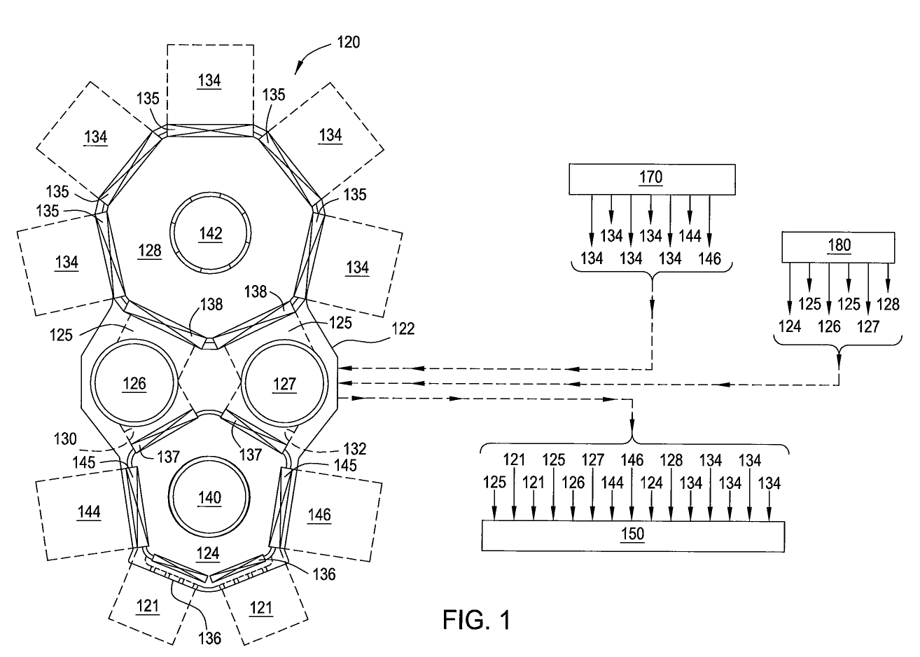

FIG. 1 is a schematic plan view of the configuration of substrate processing system 120. Substrate processing system 120 includes mainframe housing 122 which contains multiple chambers. For example, FIG. 1 depicts mainframe housing 122 containing four chambers which include buffer chamber 124 and transfer chamber 128 at opposite ends and a pair of treatment chambers 126 and 127 disposed intermediately therebetween. Substrate processing system 120 has at least one load lock chamber 121 coupled to mainframe housing 122, such as the two load lock chambers 121 which are mounted to buffer chamber 124. Each load lock chamber 121 is in fluid communication with the interior of buffer chamber 124 via one of the slit valves 136. Load lock chambers 121 coupled to mainframe housing 122 are usually the only chambers that are exposed to atmospheric pressure or conditions and are used for loading substrates into substrate processing system 120.

Mainframe housing 122 is vacuum tight structure through which substrates are transferred between multiples chambers therein. Mainframe housing 122 may be a monolithic structure, such as machined from or otherwise fabricated of one piece of material. Mainframe housing 122 may be made from or contain aluminum, an aluminum alloy, steel, stainless steel, or another metal alloy. The use of the monolith construction facilitates alignment of the individual chambers for substrate transport and also eliminates difficulties in sealing the individual chambers. Mainframe housing 122 may contain four chambers, such as buffer chamber 124, treatment chambers 126 and 127, and transfer chamber 128, which are interconnected by corridors 125 having pathways 130 and 132.

Transfer chamber 128 is separated from buffer chamber 124 by one of the corridors 125 along pathways 130 or 132, and through treatment chambers 126 and 127 and slit valves 137 and 138. A substrate may be transferred between buffer chamber 124 and transfer chamber 128 via treatment chamber 126 through corridor 125 along pathway 130 or via treatment chamber 127 through corridor 125 along pathway 132. In one example of a typical process path, a substrate may be transferred from buffer chamber 124, through slit valve 137, to treatment chamber 126 along pathway 130 of corridor 125, through slit valve 138, into transfer chamber 128, through slit valve 135, and into processing chamber 134. The substrate may be transferred in and out of multiple slit valves 135 and processing chambers 134 to be exposed to various processing techniques unique to the specific type of processing chamber 134. Subsequently, the substrate may be transferred in the opposite direction to be removed from substrate processing system 120. For example, the substrate may be transferred from transfer chamber 128, through slit valve 138, to treatment chamber 127 along pathway 131 of corridor 125, through slit valve 137, into buffer chamber 124, and subsequently into either one of the processing chambers 144 or 146 via slit valve 145 or into load lock chamber 121 via slit valves 136.

Buffer chamber 124 houses substrate handling robot 140 for handling substrates, and which may be used to transfer substrates from one of the load lock chambers 121 via a port or slit valve 136. Substrate handling robot 140 also may be used to transfer substrates throughout buffer chamber 124 and to and from the various processing chambers 144, 146 and treatment chambers 126, 127. Transfer chamber 128 also houses substrate handling robot 142 for handling substrates. Substrate handling robot 142 may be used to transfer substrates throughout transfer chamber 128 and to and from the multiple processing chambers 134 and treatment chambers 126, 127.

In embodiments described herein, either or both of the substrate handling robots 140 and 142 may be a dual four-bar link robot similar to the robot disclosed in commonly assigned U.S. Pat. No. 5,292,393, which is incorporated herein by reference. This robot is preferred for the use in buffer chamber 124 in part because the robot combines a folded, very compact configuration and footprint with a relatively long reach and, thus, the capability to service the cassette load locks, such as load lock chamber 121, as well as processing chambers 144, 146, and treatment chambers 126, 127.

A plurality of processing chambers 134 (illustratively five) are mounted about the periphery of transfer chamber 128. Each of processing chambers 134 is connected to the transfer chamber 128 and has slit valve 135 that can be closed to isolate each individual processing chamber 134 from the transfer chamber 128, or opened to independently allow substrate handling robot 142 to load or unload substrates. Similar, each of the processing chambers 144 and 146 is connected to buffer chamber 124 and has slit valve 145 that can be closed to independently isolate the processing chamber 144 or 146 from buffer chamber 124, or opened to independently allow substrate handling robot 140 to load or unload substrates.

Processing chambers 134 may be adapted for various types of fabrication or processing such as etching and/or depositing materials from/to a substrate. In embodiments described herein, substrate processing system 120 may be configured a variety of different type of chambers as processing chambers 134. In some examples, each of the processing chambers 134 may independently be a PVD chamber, a CVD chamber (thermal or plasma), an ALD chamber (thermal or plasma), an anneal chamber (thermal or plasma), or mixtures thereof. Access is provided to and from each of processing chambers 134 within transfer chamber 128 by an associated ports, gate valve, or slit valve 135.

Buffer chamber 124 and transfer chamber 128 are in fluid communication with one another via the intermediate processing or treatment chambers 126 and 127 (also called “treatment” chambers). Treatment chamber 126 is disposed within corridor 125 and between transfer chamber 128 and buffer chamber 124, similar as treatment chamber 127 is disposed within corridor 125 and also between transfer chamber 128 and buffer chamber 124. Specifically, treatment chamber 126 is located along corridor 125 having pathway 130 which connects transfer chamber 128 to buffer chamber 124. Similarly, treatment chamber 127 is located along a separate corridor or pathway 132 which also connects transfer chamber 128 to buffer chamber 124. These separate process flows or paths, pathways 130 and 132, between buffer chamber 124 and transfer chamber 128 permit one path to be used for loading or unloading while substrate processing system 120 is being used for substrate processing treatment and, thus, provide increased throughput. Treatment chambers 126 and 127 can be dedicated to pre-treating (e.g., plasma etch cleaning and/or heating) of the substrates before processing in processing chambers 134 or post-treating (e.g., cool-down) of the substrates following treatment in processing chambers 134. Alternatively, one or both of treatment chambers 126 and 127 can be adapted for both pre-treatment and post-treatment.

In one embodiment, one type of an operational cycle for transporting and processing substrates through substrate processing system 120 begins by removing a substrate from cassette load lock chamber 121 by using a substrate handling robot 140 and transporting the substrate into buffer chamber 124. Thereafter, the substrate may be transferred into one of the processing chambers 144 or 146 coupled to buffer chamber 124. In one example, processing chamber 144 or 146 is a vapor deposition chamber and the substrate is exposed to a halogenated compound to deposit a material on the substrate during a vapor deposition process, such as a CVD process or an ALD process. In another example, processing chamber 144 or 146 is a preclean chamber and the substrate is exposed to a halogenated compound to etch or clean the substrate during an etch process or a preclean process. The method further includes transferring the substrate from processing chamber 144 or 146 and into buffer chamber 124 by substrate handling robot 140 while maintaining a greater internal pressure within buffer chamber 124 than in processing chamber 144 or 146.

The method may further include flowing at least one gas into buffer chamber 124 and evacuating processing chamber 144 or 146 while transferring the substrate from processing chamber 144 or 146 to buffer chamber 124. Gases which may be flowed into buffer chamber 124 include argon, nitrogen, helium, or mixtures thereof. The method may further include maintaining a port, a gate valve, or a slit valve, such as one of the slit valves 145, in an open position while transferring the substrate from processing chamber 144 or 146 to buffer chamber 124.

In some examples, the internal pressure of buffer chamber 124 may be maintained at about 1 Torr or greater and the internal pressure of processing chamber 144 or 146 may be maintained at about 100 milliTorr or lower while transferring the substrate from processing chamber 144 or 146 to buffer chamber 124. In other examples, the internal pressure of buffer chamber 124 may be maintained at about 10 Torr or greater and the internal pressure of processing chamber 144 or 146 may be maintained at about 10 milliTorr or lower while transferring the substrate.

Subsequently, substrate handling robot 140 transfers the substrate from one of the processing chambers 144 or 146 into buffer chamber 124 during the purge process, and then into one of the treatment chambers 126 or 127 which could be a preclean chamber or a degassing chamber of the substrate. The substrate may be exposed to a precleaning process, a degassing process, an annealing process, or a cooling process while in treatment chambers 126 or 127. Substrate handling robot 142 in transfer chamber 128 picks up the substrate from treatment chamber 126 and transfers the substrate into the cavity of transfer chamber 128, then into one of the high vacuum processing chambers 134, such as a PVD chamber. Following processing, substrate handling robot 142 may transfer the substrate selectively to one or more of the other processing chambers 134 for further processing, such as a deposition process. Then, following use of this random access-type transfer capability, substrate handling robot 142 transfers the substrate to treatment chamber 127 which may be a cool-down chamber. After the cool-down cycle, substrate handling robot 140 retrieves the substrate from treatment chamber 127 and returns the substrate to the appropriate cassette load lock chamber 121.

Substrate processing system 120 is uniquely designed so that each chamber stage (processing chambers 134, transfer chamber 124, treatment chambers 126, 127, buffer chamber 124, and/or load lock chambers 121) can be isolated from all the other chambers. None of the chambers or stages, with the exception of the cassette load lock chambers 121, is vented to atmosphere during processing. In some embodiments, during substrate transfer, as little as two adjacent chambers may be in fluid communication at any time, although three or more adjacent chambers may be in fluid communication at any time by opening slit valves therebetween. As a result, variations in pressure or vacuum level during substrate transfer may be controlled by using vacuum system 150 and gas source 180, as depicted in FIG. 1.

A vacuum gradient may be formed to extend across the system from the cassette load lock chamber 121 to processing chambers 134 while increasing in pressure. The staged vacuum is applied across the system with the degree of vacuum increasing in order from the cassette load lock chambers 121 to processing chambers 134. Consequently, the time required to pump down processing chamber 134 to a base vacuum level subsequent to the loading of a substrate therein is minimized and very high degrees of vacuum can be used in processing chambers 134 without lengthy pump down times and, thus, without adversely affecting system throughput. Also, since the substrates can be pre-cleaned and/or pre-heated before entering high vacuum, there is less system contamination and throughput is increased.

In addition to the enhanced vacuum isolation, throughput and processing versatility provided by the intermediate stage chambers, treatment chambers 126 and 127, the abovementioned stations or processing chambers 144 and 146 may be coupled to, coupled with, or mounted on buffer chamber 124 to provide still additional processing isolation, flexibility, and throughput enhancement. In some embodiments, processing chambers 144 and 146 may be adapted for various types of fabrication or processing including etching and/or depositing materials from/to a substrate, similar to processing chambers 134. Substrate processing system 120 may be configured a variety of different type of chambers as processing chambers 144 and 146. In some examples, each of the processing chambers 144 and 146 may independently be a PVD chamber, a CVD chamber (thermal or plasma), an ALD chamber (thermal or plasma), an anneal chamber (thermal or plasma), a degas chamber, a preclean chamber, or mixtures thereof. Access is provided to and between each of processing chambers 144 and 146 by an associated port, gate valve, or slit valve 145.

In one embodiment, substrate processing system 120 may be configured having processing chamber 144 as a vapor deposition chamber (e.g., CVD or ALD chamber), processing chamber 146 as a vapor deposition chamber (e.g., CVD or ALD chamber), each of the processing chambers 134 as a deposition chamber (e.g., PVD, CVD, or ALD chamber). In many examples, at least one and up to five of the processing chambers 134 may be PVD chambers coupled to transfer chamber 128 while processing chambers 144 and/or 146 coupled to buffer chamber 124 may be a CVD chamber and/or an ALD chamber. During substrate processing, transfer chamber 128 may be maintained under a high vacuum while buffer chamber 124 may be maintained at a pressure greater than one of the processing chambers 144 or 146.

In other embodiments, processing chamber 144 may be an orientater which is used to orient the wafer or substrate flats prior to processing. Alternatively, an entire cassette of substrates in load lock chamber 121 may be oriented one at a time preparatory to transfer to the processing chambers. Processing chamber 146 may also be dedicated to pre-processing treatment. Alternatively, one or both of processing chambers 144 and 146 may be used for post-processing treatment, for both pre-processing and post-processing treatment, or for processing itself. Processing chambers 144 and 146 are very effectively isolated from processing chambers 134 by the intervening individually isolated buffer chamber 124, treatment chambers 126 and 127, and transfer chamber 128. Thus, processing chambers 144 and 146 may be conveniently used for processes which require a different (and/or incompatible) chemistry and/or different (typically lower) pressure relative to the group of processing chambers 134. For example, the high degree of isolation facilitates the use of corrosive gas chemistry in processing chambers 134 without affecting the atmosphere and processing/treatment in processing chambers 144 and 146, and vice versa.

Gas source 180 and vacuum system 150 may be operated to maintain a higher pressure within buffer chamber 124 relative to the pressure(s) within either or both of the processing chambers 144 and 146 during the transferring of the substrate. Gas source 180 provides at least one gas to buffer chamber 124, transfer chamber 128, treatment chambers 126 and 127, and corridors 125. A gas flow within mainframe housing 122 flows from buffer chamber 124 towards and into either or both of the processing chambers 144 and 146. The purge gases containing contaminants and/or corrosive compounds are removed from processing chambers 144 and 146 by vacuum system 150.

In some examples, vacuum system 150 and/or gas source 180 may be utilized to maintain the internal pressure of buffer chamber 124 at about 1 Torr or greater while the internal pressure of processing chamber 144 or 146 is maintained at about 100 milliTorr or lower, such as while transferring the substrate between processing chamber 144 or 146 and buffer chamber 124. In other examples, the internal pressure of buffer chamber 124 may be maintained at about 10 Torr or greater and the internal pressure of processing chamber 144 or 146 may be maintained at about 10 milliTorr or lower while transferring the substrate between processing chamber 144 or 146 and buffer chamber 124.

Vacuum system 150 is provided to maintain the interior volume of the chambers under vacuum or at least with a reduced pressure and also to reduce or to remove various gases from within the interior of the chambers. Vacuum system 150 is coupled to and in fluid communication with each of the chambers within substrate processing system 120. For example, vacuum system 150 is coupled to and in fluid communication with load lock chambers 121, processing chambers 134, 144, and 146, buffer chamber 124, transfer chamber 128, treatment chambers 126 and 127, and corridors 125. Therefore, the pressure of each of the load lock chambers 121, the processing chambers 134, 144, or 146, buffer chamber 124, transfer chamber 128, the treatment chambers 126 or 127, and the corridors 125 may be simultaneously maintained at different pressures by vacuum system 150. Vacuum system 150 may pull a vacuum from various types of pumps such as cryo-pumps, dry pumps, turbo pumps or an in-house pumping system.

Vacuum system 150 may be used to pump down and maintain a base pressure during processing techniques (e.g., PVD, ALD, CVD, pre-clean) for the various chambers within substrate processing system 120. In some embodiments, buffer chamber 124 may be have a base pressure of about 5×10⁻⁶ Torr, transfer chamber 128 may be have a base pressure of about 5×10⁻⁸ Torr, and treatment chambers 126 and 127 may each independently have a base pressure of about 5×10⁻⁸ Torr, while processing techniques are performed within substrate processing system 120. In other embodiments, processing chambers 134, 144, or 146 may each independently have a base pressure of about 3×10⁻⁸ Torr if a PVD chamber and during a PVD process, a base pressure of about 5×10⁻⁶ Torr if a CVD chamber and during a CVD process, a base pressure of about 5×10⁻⁶ Torr if an ALD chamber and during an ALD process, a base pressure of about 1×10⁻⁷ Torr if a preclean chamber and during a preclean process, and/or a base pressure of about 5×10⁻⁷ Torr if a degas chamber and during a degas process.

In one embodiment, gas source 180 may be coupled to and in fluid communication with each of the chambers within substrate processing system 120. Gas source 180 is provided to maintain the interior volume of the chambers with specified gases. For example, gas source 180 may be independently coupled to and in fluid communication with processing chambers 134, 144, and 146, buffer chamber 124, transfer chamber 128, treatment chambers 126 and 127, and corridors 125. Therefore, the pressure of each of the processing chambers 134, 144, or 146, buffer chamber 124, transfer chamber 128, the treatment chambers 126 or 127, and the corridors 125 may be simultaneously maintained at different pressures by gas source 180 in conjunction with vacuum system 150. In some embodiments, gas source 180 may also supply gases to process gas source 170 in order to supply specific gases to the individual chambers within substrate processing system 120. For example, gas source 180 may supply gases to each of the processing chambers 134, 144, and 146 via process gas source 170.

Gas source 180 may be a source of an inert gas, a carrier gas, purge gas, a flushing gas, a plasma source gas, or mixtures thereof. In some embodiments, gas source 180 is an inert gas source and provides an inert gas, such as argon, nitrogen, helium, neon, or mixtures thereof, to the interior volume of the various chambers within substrate processing system 120. In one example, gas source 180 provides an inert gas to buffer chamber 124 to assist, in conjunction with vacuum system 150, in maintaining the pressure of buffer chamber 124 at a pressure elevated above the pressure(s) of processing chamber 144, processing chamber 146, and/or transfer chamber 128. In another example, gas source 180 is a carrier gas source or a purge gas source and provides a gas, such as argon, nitrogen (N₂), helium, hydrogen (H₂), forming gas (e.g., a mixture of N₂/H₂ gases) or mixtures thereof, to the interior volume of buffer chamber 124 to assist, in conjunction with vacuum system 150, in maintaining the pressure of buffer chamber 124 at a pressure elevated above the pressure(s) of processing chamber 144, processing chamber 146, and/or transfer chamber 128.

In many embodiments depicted in FIG. 1, substrate processing system 120 contains at least one CVD chamber and/or ALD chamber as one of the processing chambers 134, 144, or 146. In another embodiment, substrate processing system 120 contains at least one PVD chamber as one of the processing chambers 134, 144, or 146. The CVD, ALD, and PVD chambers are coupled to process gas source 170 that provides process gases, deposition gases (e.g., chemical precursors including halogenated compounds), carrier gases, purge gases, inert gases, cleaning gases, flushing gases, plasma source gases, or mixtures thereof. Such gases may includes, by are not limited to chlorine-containing gas and/or fluorine-containing gas, among others. Halogenated compounds, such as chlorine-containing gas and/or fluorine-containing gas are usually corrosive to aluminum surfaces and other surfaces of the system or chamber components within substrate processing system 120.

Halogenated compounds may be used within substrate processing system 120 for a variety of uses including as a chemical precursor in a vapor deposition process (e.g., CVD or ALD) or as a cleaning gas, for example. In some examples, the halogenated compound may be a metal halide or a halogen gas. In some embodiments, the halogenated compound contain at least one element of F, Cl, Br, or I, and may contain at least one element of Ti, Ta, W, Mo, Co, Ru, Hf, Zr, Al, Si, Ge, Ga, N, B, P, As, In, Sn, Sb, or others. Some exemplary halogenated compounds include titanium tetrachloride (TiCl₄), tantalum pentafluoride (TaF₅), tungsten hexafluoride (WF₆), hafnium tetrachloride (HfCl₄), aluminum trichloride (AlCl₃), silicon tetrachlorosilane (SiCl₄), hexachlorodisilane (Si₂Cl₆), zirconium fluoride (ZrF₄), zirconium chloride (ZrCl₄), radicals thereof, ions thereof, derivatives thereof, or combinations thereof. Other exemplary halogenated compounds include nitrogen trifluoride (NF₃), xenon difluoride (XeF₂), trifluoroborane (BF₃), chlorine gas (Cl₂), fluorine gas (F₂), hydrogen chloride (HCl), hydrogen fluoride (HF), radicals thereof, ions thereof, derivatives thereof, or combinations thereof.

Buffer chamber 124 may be maintained at a pressure greater than that of processing chambers 144 or 146 during purge and evacuation processes described herein. Once a deposition or other process has been competed within either or both of processing chambers 144 or 146, then vacuum system 150 may be utilized to start pumping down or evacuating processing chambers 144 and 146. Also, the pressure within buffer chamber 124 may be increased by flowing a purge gas, an inert gas or another gas into buffer chamber 124.

In some examples, buffer chamber 124 may have an internal pressure of about 1 Torr or greater, such as within a range from about 10 Torr to about 50 Torr. Either processing chamber 144 or 146 may be maintained at a pressure of less than that of buffer chamber 124. In some examples, processing chambers 144 or 146 may have an internal pressure of less than about 1 Torr, such as about 900 milliTorr or lower, about 500 milliTorr or lower, about 200 milliTorr or lower, about 100 milliTorr or lower, or about 50 milliTorr or lower. By maintaining the pressure of buffer chamber 124 at a pressure above that of processing chambers 144 or 146, the flow of corrosive chemicals which may escape from processing chambers 144 or 146 may be prevented from reaching buffer chamber 124, transfer channel, and processing chambers 134. In one embodiment, buffer chamber 124 is maintained at a pressure of at least 10 times the pressure of either processing chambers 144 or 146.

In an alternative embodiment, if more steps of the process may benefit the use of a CVD process, a cleaning process, or other processes which use corrosive chemicals, such that processing chambers 134 attached to the transfer chamber 128 to be used for these parts of the process, the transfer chamber 128 may also be maintained at higher pressure to prevent the flow of corrosive gases from the processing chambers into the transfer chamber or other parts of the mainframe. In the alternative, if it were desirable to have CVD or other processes using corrosive gases performed in the processing chambers attached to the transfer chamber and to perform processes that do not use corrosive chemicals in the processing chambers attached to the buffer chamber, the pressure in the transfer chamber 128 could be maintained at a level greater than processing chambers 134 while the pressure in the buffer chamber is maintained at a level below the pressure within processing chambers 144 and 146 attached to buffer chamber 124.

The elimination or minimization of the flow of corrosive gases into the mainframe is among the benefits of the processes described in embodiments herein. This eliminates or minimizes the corrosion of the mainframe parts and contamination of the sputtering target for a sputtering process, and eliminates or minimizes the need to coat or deposit the interior of the mainframe, the robots, or other parts with nickel or other metals for reducing corrosion of those parts. This allows for lower costs of manufacturing substrate processing systems and a reduction in the potential for defects in the substrate coating process.

Embodiments of the invention provide methods for processing substrates within a substrate processing system. In one embodiment, the method provides depositing a first material on a substrate within a vapor deposition chamber coupled to a buffer chamber contained within a mainframe housing of the substrate processing system, wherein the buffer chamber contains a first substrate handling robot, maintaining an internal pressure of about 1×10⁻⁶ Torr or lower within a transfer chamber contained within the mainframe housing, wherein at least one PVD chamber is coupled to the transfer chamber and the transfer chamber contains a second substrate handling robot. The method further includes transferring the substrate from the vapor deposition chamber to the buffer chamber by the first substrate handling robot while maintaining a greater internal pressure within the buffer chamber than in the vapor deposition chamber, transferring the substrate from the buffer chamber to the transfer chamber, transferring the substrate from the transfer chamber to the PVD chamber by the second substrate handling robot, and depositing a second material over the substrate within the PVD chamber.

The method may further include flowing at least one gas into the buffer chamber and evacuating the vapor deposition chamber while transferring the substrate from the vapor deposition chamber to the buffer chamber. Gases which may be flowed into the buffer chamber include argon, nitrogen, helium, or mixtures thereof. The method may further include maintaining a slit valve in an open position while transferring the substrate from the vapor deposition chamber to the buffer chamber. The slit valve is disposed between the buffer chamber and the vapor deposition chamber.

In some examples, the internal pressure of the buffer chamber may be maintained at about 1 Torr or greater and the internal pressure of the vapor deposition chamber may be maintained at about 100 milliTorr or lower while transferring the substrate from the vapor deposition chamber to the buffer chamber. In other examples, the internal pressure of the buffer chamber may be maintained at about 10 Torr or greater and the internal pressure of the vapor deposition chamber may be maintained at about 10 milliTorr or lower while transferring the substrate.

In some embodiments, the method further includes transferring the substrate from the buffer chamber to a treatment chamber by the first substrate handling robot and subsequently, transferring the substrate from the treatment chamber to the buffer chamber by the second substrate handling robot. The treatment chamber is disposed between the transfer chamber and the buffer chamber. A first slit valve is disposed between the transfer chamber and the treatment chamber and a second slit valve is disposed between the buffer chamber and the treatment chamber.

The first material may be deposited during a vapor deposition process, such as a CVD process or an ALD process, therefore, the vapor deposition chamber may be a CVD chamber or an ALD chamber. During the vapor deposition process, at least one corrosive compound, such a halogenated compound, may be delivered into the vapor deposition chamber while forming or depositing the first material on the substrate. In some examples, the halogenated compound contains chlorine or fluorine. Exemplary halogenated compounds include titanium tetrachloride, tantalum pentafluoride, tungsten hexafluoride, hafnium tetrachloride, aluminum trichloride, silicon tetrachlorosilane, hexachlorodisilane, derivatives thereof, and combinations thereof.

In another embodiment, the method provides depositing a material on a substrate within a vapor deposition chamber coupled to a buffer chamber contained within a mainframe housing of the substrate processing system, wherein the buffer chamber contains a first substrate handling robot, maintaining an internal pressure of about 1×10⁻⁵ Torr or lower within a transfer chamber contained within the mainframe housing, wherein at least one PVD chamber is coupled to the transfer chamber and the transfer chamber contains a second substrate handling robot, and transferring the substrate from the vapor deposition chamber to the buffer chamber by the first substrate handling robot while maintaining a greater internal pressure within the buffer chamber than in the vapor deposition chamber. In some examples, the internal pressure of the transfer chamber is maintained within a range from about 5×10⁻⁸ Torr to about 1×10⁻⁶ Torr.

In another embodiment, the method provides depositing a material on a substrate within a vapor deposition chamber coupled to a buffer chamber contained within a mainframe housing of the substrate processing system, wherein the material is deposited during a vapor deposition process and at least one halogenated compound is delivered into the vapor deposition chamber during the vapor deposition process. The method further includes transferring the substrate from the vapor deposition chamber to the buffer chamber while maintaining a greater internal pressure within the buffer chamber than in the vapor deposition chamber, flowing at least one gas into the buffer chamber, and evacuating the vapor deposition chamber. The method may further include maintaining a slit valve in an open position while transferring the substrate from the vapor deposition chamber to the buffer chamber, wherein the slit valve is disposed between the buffer chamber and the vapor deposition chamber.

This substrate processing system and method for using such a system disclosed in this application could use buffer chambers, transfer chambers, load lock chambers, treatment chambers, pathways, robots, and other components of various geometries, sizes, or quantities different than those depicted in FIG. 1.

While the foregoing is directed to embodiments of the invention, other and further embodiments of the invention may be devised without departing from the basic scope thereof, and the scope thereof is determined by the claims that follow.

What is claimed is:

1. A method for processing a substrate within a substrate processing system, comprising:
depositing a first material on a substrate within a vapor deposition chamber coupled to a buffer chamber contained within a mainframe housing of the substrate processing system, wherein the buffer chamber contains a first substrate handling robot;
maintaining an internal pressure of about 1×10⁻⁶ Torr or lower within a transfer chamber contained within the mainframe housing, wherein at least one physical vapor deposition chamber is coupled to the transfer chamber and the transfer chamber contains a second substrate handling robot;
transferring the substrate from the vapor deposition chamber to the buffer chamber by the first substrate handling robot while maintaining a greater internal pressure within the buffer chamber than in the vapor deposition chamber;
transferring the substrate from the buffer chamber to the transfer chamber;
transferring the substrate from the transfer chamber to the physical vapor deposition chamber by the second substrate handling robot; and
depositing a second material over the substrate within the physical vapor deposition chamber.

2. The method of claim 1, further comprising flowing at least one gas into the buffer chamber and evacuating the vapor deposition chamber while transferring the substrate from the vapor deposition chamber to the buffer chamber.

3. The method of claim 2, wherein the at least one gas comprises argon, nitrogen, helium, or mixtures thereof.

4. The method of claim 2, further comprising maintaining a slit valve in an open position while transferring the substrate from the vapor deposition chamber to the buffer chamber, wherein the slit valve is disposed between the buffer chamber and the vapor deposition chamber.

5. The method of claim 4, wherein the internal pressure of the buffer chamber is maintained at about 1 Torr or greater and the internal pressure of the vapor deposition chamber is maintained at about 100 milliTorr or lower while transferring the substrate from the vapor deposition chamber to the buffer chamber.

6. The method of claim 5, wherein the internal pressure of the buffer chamber is maintained at about 10 Torr or greater and the internal pressure of the vapor deposition chamber is maintained at about 10 milliTorr or lower.

7. The method of claim 1, wherein the first material is deposited during a vapor deposition process, and at least one halogenated compound is delivered into the vapor deposition chamber during the vapor deposition process.

8. The method of claim 7, wherein the vapor deposition chamber is a chemical vapor deposition chamber or an atomic layer deposition chamber, and the halogenated compound contains chlorine or fluorine.

9. The method of claim 1, wherein the transferring the substrate from the buffer chamber to the transfer chamber further comprises:
transferring the substrate from the buffer chamber to a treatment chamber by the first substrate handling robot, wherein the treatment chamber is disposed between the transfer chamber and the buffer chamber; and
transferring the substrate from the treatment chamber to the buffer chamber by the second substrate handling robot.

10. The method of claim 9, wherein a first slit valve is disposed between the transfer chamber and the treatment chamber and a second slit valve is disposed between the buffer chamber and the treatment chamber.

11. A method for processing a substrate within a substrate processing system, comprising:
depositing a material on a substrate within a vapor deposition chamber coupled to a buffer chamber contained within a mainframe housing of the substrate processing system, wherein the buffer chamber contains a first substrate handling robot;
maintaining an internal pressure of about 1×10⁻⁵ Torr or lower within a transfer chamber contained within the mainframe housing, wherein at least one physical vapor deposition chamber is coupled to the transfer chamber and the transfer chamber contains a second substrate handling robot; and
transferring the substrate from the vapor deposition chamber to the buffer chamber by the first substrate handling robot while maintaining a greater internal pressure within the buffer chamber than in the vapor deposition chamber.

12. The method of claim 11, wherein the internal pressure of the buffer chamber is maintained at about 1 Torr or greater and the internal pressure of the vapor deposition chamber is maintained at about 100 milliTorr or lower while transferring the substrate from the vapor deposition chamber to the buffer chamber.

13. The method of claim 12, wherein the internal pressure of the buffer chamber is maintained at about 10 Torr or greater and the internal pressure of the vapor deposition chamber is maintained at about 10 milliTorr or lower.

14. The method of claim 11, wherein the internal pressure of the transfer chamber is maintained within a range from about 5×10⁻⁸ Torr to about 1×10⁻⁶ Torr.

15. The method of claim 11, further comprising flowing at least one gas into the buffer chamber and evacuating the vapor deposition chamber while transferring the substrate from the vapor deposition chamber to the buffer chamber.

16. The method of claim 15, wherein the at least one gas comprises argon, nitrogen, helium, or mixtures thereof.

17. A method for processing a substrate within a substrate processing system, comprising:
depositing a material on a substrate within a vapor deposition chamber coupled to a buffer chamber contained within a mainframe housing of the substrate processing system, wherein the material is deposited during a vapor deposition process and at least one halogenated compound is delivered into the vapor deposition chamber during the vapor deposition process; and
transferring the substrate from the vapor deposition chamber to the buffer chamber while:
maintaining a greater internal pressure within the buffer chamber than in the vapor deposition chamber;
flowing at least one gas into the buffer chamber; and
evacuating the vapor deposition chamber.

18. The method of claim 17, wherein the internal pressure of the buffer chamber is maintained at about 1 Torr or greater and the internal pressure of the vapor deposition chamber is maintained at about 100 milliTorr or lower while transferring the substrate from the vapor deposition chamber to the buffer chamber.

19. The method of claim 18, wherein the internal pressure of the buffer chamber is maintained at about 10 Torr or greater and the internal pressure of the vapor deposition chamber is maintained at about 10 milliTorr or lower.

20. The method of claim 19, wherein the at least one gas comprises argon, nitrogen, helium, or mixtures thereof.

21. The method of claim 17, wherein the buffer chamber contains a substrate handling robot for transferring the substrate to and from the vapor deposition chamber.

22. The method of claim 21, further comprising maintaining a slit valve in an open position while transferring the substrate from the vapor deposition chamber to the buffer chamber, wherein the slit valve is disposed between the buffer chamber and the vapor deposition chamber.

23. The method of claim 17, wherein the halogenated compound contains chlorine or fluorine.

24. The method of claim 23, wherein the halogenated compound is selected from the group consisting of titanium tetrachloride, tantalum pentafluoride, tungsten hexafluoride, hafnium tetrachloride, aluminum trichloride, silicon tetrachlorosilane, hexachlorodisilane, derivatives thereof, and combinations thereof.

25. The method of claim 23, wherein the vapor deposition chamber is a chemical vapor deposition chamber or an atomic layer deposition chamber.
